(19) United States
(12) Patent Application Publication
(10) Pub. No.: US 2025/0311359 A1
(43) Pub. Date: Oct. 2, 2025

(54) SEMICONDUCTOR STRUCTURE WITH DIELECTRIC GATE CAP

(71) Applicant: International Business Machines Corporation, Armonk, NY (US)

(72) Inventors: Ruilong Xie, Niskayuna, NY (US); Lawrence Alfred Clevenger, Saratoga Springs, NY (US); Reinaldo Vega, Mahopac, NY (US); Nicholas Anthony Lanzillo, Wynantskill, NY (US)

(21) Appl. No.: 18/623,210

(22) Filed: Apr. 1, 2024

(51) Int. Cl. H01L 29/66; H01L 27/088; H01L 29/06; H01L 29/08; H01L 29/423; H01L 29/786

(52) U.S. Cl. CPC H10D 64/021; H10D 30/6735; H10D 30/6757; H10D 62/118; H10D 62/151; H10D 84/83

(57) ABSTRACT

A semiconductor structure includes gate sidewall spacers disposed on sidewalls of a gate structure, a dielectric gate cap disposed over a portion of the gate structure, and a dielectric sidewall spacer disposed on sidewalls of the dielectric gate cap and on the gate structure, wherein the dielectric sidewall spacer extends into a gate recess region arranged between the gate structure and a given one of the gate sidewall spacers and surrounds the dielectric gate cap.

### BACKGROUND

Semiconductors and integrated circuit chips have become ubiquitous within many products, particularly as they continue to decrease in cost and size. There is a continued desire to reduce the size of structural features and/or to provide a greater number of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Illustrative embodiments of the present application include techniques for use in semiconductor manufacture. In an illustrative embodiment, a semiconductor structure includes gate sidewall spacers disposed on sidewalls of a gate structure, a dielectric gate cap disposed over a portion of the gate structure, and a dielectric sidewall spacer disposed on sidewalls of the dielectric gate cap and on the gate structure, wherein the dielectric sidewall spacer extends into a gate recess region arranged between the gate structure and a given one of the gate sidewall spacers and surrounds the dielectric gate cap.

In an illustrative embodiment, a semiconductor structure includes first gate sidewall spacers disposed on sidewalls of a first gate structure on a first channel region, a first dielectric gate cap disposed over a portion of the first gate structure, a first dielectric sidewall spacer disposed on sidewalls of the first dielectric gate cap, wherein the first dielectric sidewall spacer extends into a gate recess region arranged between the first gate structure and a given one of the first gate sidewall spacers and surrounds the first dielectric gate cap, second gate sidewall spacers disposed on sidewalls of a second gate structure on a second channel region adjacent the first channel region, a second dielectric gate cap disposed over the second gate structure, and a second dielectric sidewall spacer disposed on sidewalls of the second dielectric gate cap and surrounds the second dielectric gate cap.

In yet another illustrative embodiment, an integrated circuit includes one or more semiconductor structures. At least one of the one or more semiconductor structures is a semiconductor device according to one or more of the foregoing illustrative embodiments.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1A depicts a top-down view illustrating a semiconductor structure during an intermediate step of a method of fabricating a nanosheet transistor structure, according to an illustrative embodiment.

FIG. 1B is a cross-sectional view illustrating the semiconductor structure taken along the X-X axis of FIG. 1A, according to an illustrative embodiment.

FIG. 2 is a cross-sectional view of the semiconductor structure taken along the X-X axis of FIG. 1A following deposition of a dielectric layer, according to an illustrative embodiment.

FIG. 3 is a cross-sectional view of the semiconductor structure taken along the X-X axis of FIG. 1A following formation of dielectric gate caps, according to an illustrative embodiment.

FIG. 4 is a cross-sectional view of the semiconductor structure taken along the X-X axis of FIG. 1A following formation of a gate recess region, according to an illustrative embodiment.

FIG. 5 is a cross-sectional view of the semiconductor structure taken along the X-X axis of FIG. 1A following deposition of a dielectric sidewall spacer on the dielectric gate caps, according to an illustrative embodiment.

FIG. 6 is a cross-sectional view of the semiconductor structure taken along the X-X axis of FIG. 1A following formation of source/drain contact openings, according to an illustrative embodiment.

FIG. 7 is a cross-sectional view of the semiconductor structure taken along the X-X axis of FIG. 1A following enlarging and cleaning the source/drain contact openings, according to an illustrative embodiment.

FIG. 8 is a cross-sectional view of the semiconductor structure taken along the X-X axis of FIG. 1A following formation of source/drain metal contacts, according to an illustrative embodiment.

FIG. 9 is a cross-sectional view of the semiconductor structure taken along the X-X axis of FIG. 1A following deposition of another ILD layer, followed by a planarization process, according to an illustrative embodiment.

FIG. 10 is a cross-sectional view of the semiconductor structure taken along the X-X axis of FIG. 1A following deposition and patterning of another mask layer, according to an illustrative embodiment.

FIG. 11 is a cross-sectional view of the semiconductor structure taken along the X-X axis of FIG. 1A following formation of a gate contact opening, according to an illustrative embodiment.

FIG. 12A a top-down view of the semiconductor structure following deposition of an additional mask layer, followed by patterning and etching source/drain contact vias, according to an illustrative embodiment.

FIG. 12B is a cross-sectional view of the semiconductor structure taken along the X1-X1 axis of FIG. 12A, according to an illustrative embodiment.

FIG. 12C is a cross-sectional view of the semiconductor structure taken along the X2-X2 axis of FIG. 12A, according to an illustrative embodiment.

FIG. 13A a top-down view of the semiconductor structure following formation of metal vias and metal gate contacts, according to an illustrative embodiment.

FIG. 13B is a cross-sectional view of the semiconductor structure taken along the X1-X1 axis of FIG. 13A, according to an illustrative embodiment.

FIG. 13C is a cross-sectional view of the semiconductor structure taken along the X2-X2 axis of FIG. 13A, according to an illustrative embodiment.

### DETAILED DESCRIPTION

This disclosure relates generally to semiconductor devices, and more particularly to semiconductor structures having a middle-of-line contact, and methods for their fabrication. However, it is to be understood that embodiments of the present disclosure are not limited to the illustrative methods, apparatus, systems and devices but instead are more broadly applicable to other suitable methods, apparatus, systems and devices.

Detailed embodiments of the semiconductor structures and methods are disclosed herein. The method steps described below do not form a complete process flow for manufacturing integrated circuits, such as, semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element.

As used herein, “lateral,” “lateral side,” “lateral surface” refers to a side surface of an element (e.g., a layer, opening, etc.), such as a left or right side surface in the drawings.

As used herein, “width” or “length” refers to a size of an element (e.g., a layer, trench, hole, opening, etc.) in the drawings measured from a side surface to an opposite surface of the element.

As used herein, terms such as “upper”, “lower”, “right”, “left”, “vertical”, “horizontal”, “top”, “bottom”, and derivatives thereof are to be broadly construed to relate to the disclosed structures and methods, as oriented in the drawings, wherein such structures may be understood to have the same configuration (e.g., layers stacked in the same order) even if the structure is rotated to a different angle from that shown in the drawings.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include, but are not limited to, physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s). Other suitable techniques, such as sidewall image transfer (SIT), self-aligned double patterning (SADP), self-aligned quadruple patterning (SAQP), self-aligned multiple patterning (SAMP) can be used to etch or pattern.

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL. The conductive contacts of the MOL layer provide electrical connections between the integrated circuitry of the FEOL layer and a first level of metallization of a BEOL structure that is formed over the FEOL/MOL layers.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

The semiconductor industry has adopted non-self-aligned contact (SAC) middle-of-the-line (MOL) fabrication methods due to the simplification of the replacement metal gate process, especially in nanosheet technologies with gate lengths of approximately twelve nanometers because high-k metal gate recession at such a small dimension is very difficult. However, conventional non-SAC MOL fabrication methods prohibit formation of dual gate contacts within an active region of the semiconductor device. In addition, gate sidewall spacers are more vulnerable due to a reduced k-value of approximately 4.0 or less. Illustrative embodiments overcome the foregoing drawbacks by providing methods and structures for enabling a system and method for forming self-aligned MOL layer contacts (e.g., in two different dimensions) in small dimension nanosheet technologies while protecting low-k gate sidewall spacers with a high-k dielectric layer.

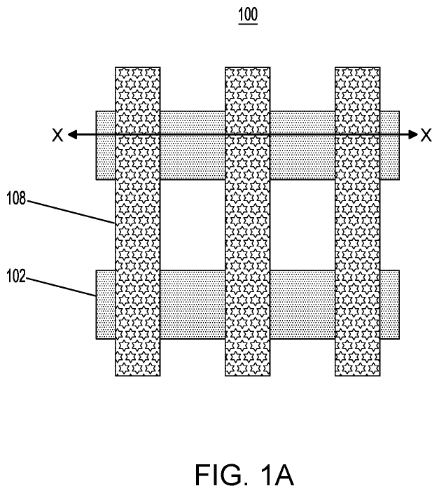

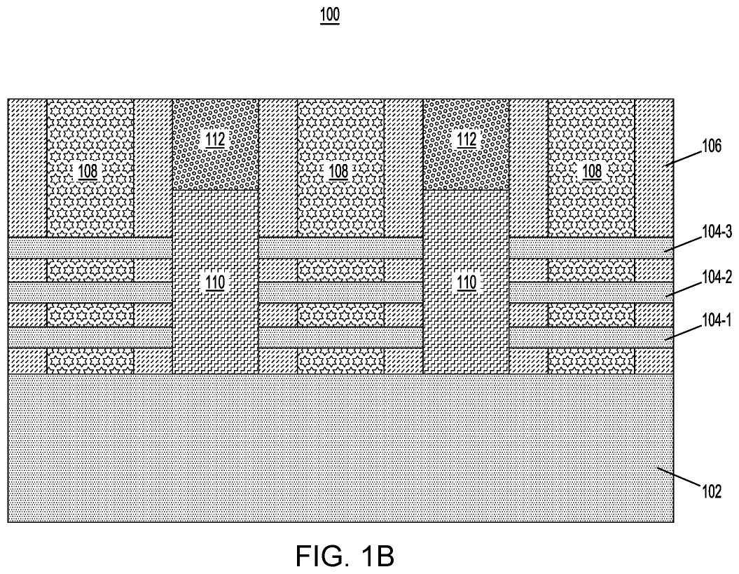

Referring now to the drawings in which like numerals represent the same or similar elements, FIGS. 1A-13C illustrate various processes for fabricating semiconductor structures with a MOL contact. Note that the same reference numeral (100) is used to denote the semiconductor structure through the various intermediate fabrication stages illustrated in FIGS. 1A-13C. Note also that the semiconductor structures described herein can also be considered to be a semiconductor device and/or an integrated circuit, or some part thereof. For the purpose of clarity, some fabrication steps leading up to the production of the semiconductor structures as illustrated in FIGS. 1A-13C are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

FIGS. 1A-13C show a semiconductor structure 100 in accordance with an illustrative embodiment. Referring now to FIG. 1A-1B, the semiconductor structure 100 is shown during an intermediate step of a method of fabricating a nanosheet transistor structure having one or more nanosheet devices according to an embodiment of the invention. The semiconductor structure 100 includes a substrate 102. The substrate 102 may be formed of any suitable semiconductor material, including various silicon-containing materials including but not limited to silicon (Si), silicon germanium (SiGe), and multi-layers thereof. Although silicon is the predominantly used semiconductor material in wafer fabrication, alternative semiconductor materials can be employed as additional layers, such as, but not limited to, SiGe, germanium (Ge), gallium arsenide (GaAs), gallium indium arsenide (InGaAs), cadmium telluride (CdTe), zinc selenide (ZnSe), etc. In one illustrative embodiment, the substrate 102 is silicon.

The semiconductor structure 100 further includes nanosheet channel layers 104-1, 104-2 and 104-3 (collectively, nanosheet channel layers 104). The nanosheet channel layers 104 may be formed of Si or another suitable material (e.g., a material similar to that used for the substrate 102).

The semiconductor structure 100 further includes gate sidewall spacers 106, gate structures 108, source/drain regions 110, and an interlayer dielectric (ILD) layer 112.

The gate sidewall spacers 106 may be formed on the sidewalls of the gate structures 108 using any convention deposition process such as ALD followed by a directional etch. In various embodiments, the gate sidewall spacers 106 may be formed of any low-k dielectric insulator material, such as SiN, silicon boron carbide nitride (SiBCN), silicon oxycarbonitride (SiOCN), or another suitable material.

In various embodiments, the gate structures 108 may include a gate dielectric layer and a gate conductor layer. The gate dielectric layer may be formed of a high-k dielectric material. Suitable high-k dielectric materials include, for example, metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k dielectric material may further include dopants such as lanthanum (La), aluminum (Al), and magnesium (Mg). The gate dielectric layer may have a uniform thickness.

In various embodiments, the gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

In various embodiments, the source/drain regions 110 may be formed using epitaxial growth processes. The source/drain regions 110 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). In some embodiments, the epitaxy process includes in-situ doping (dopants are incorporated in epitaxy material during epitaxy).

Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×1020 cm⁻³ to 3×10²¹ cm⁻³. In some embodiments, the source/drain regions 110 are p-type source/drain regions. In some embodiments, the source/drain regions 110 are n-type source/drain regions.

In various embodiments, the ILD layer 112 is formed over the source/drain regions 110 using any conventional deposition technique such as ALD, CVD, PVD, etc., followed by a planarization process (e.g., using CMP). The ILD layer 112 may be formed of any suitable isolating material, such as SiO₂, SiOC, SiON, etc.

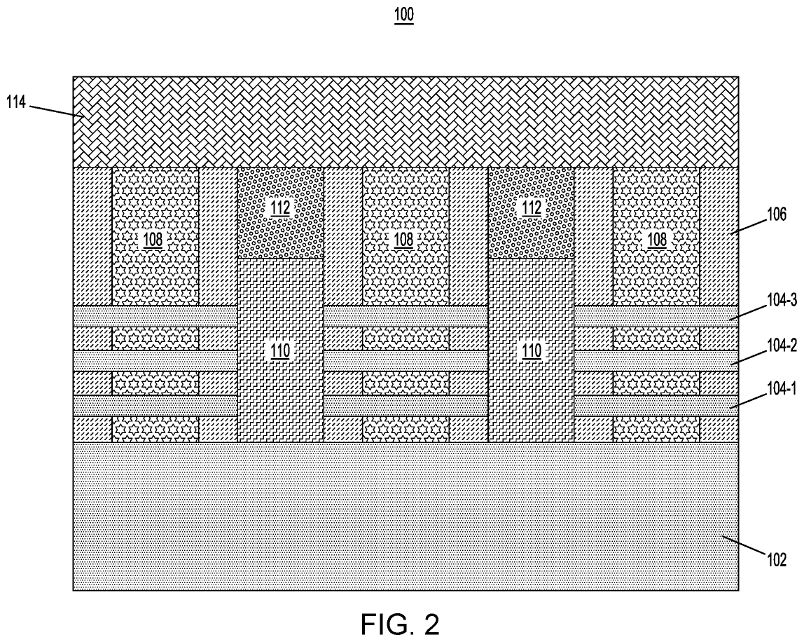

Referring now to FIG. 2, the semiconductor structure 100 is shown following deposition of a dielectric layer, according to an embodiment of the invention. A dielectric layer 114 is deposited over the semiconductor structure 100 so as to cover the gate sidewall spacers 106, the gate structures 108, and the ILD layer 112 using any conventional deposition technique such as ALD, CVD and PVD. The dielectric layer 114 may be formed of any suitable isolating material including various silicon-containing materials such as SiC and/or SiCO.

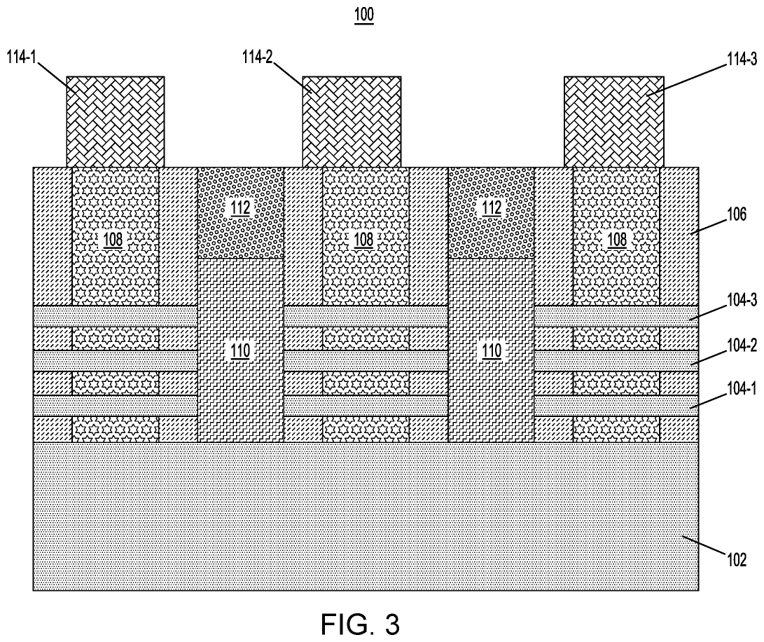

Referring now to FIG. 3, the semiconductor structure 100 is shown following formation of dielectric gate caps, according to an embodiment of the invention. Dielectric gate caps 114-1, 114-2, and 114-3 are formed by subjecting the dielectric layer 114 to standard lithographic and patterning techniques to form openings and create the dielectric gate caps 114-1, 114-2, and 114-3. In some embodiments, the dielectric gate caps 114-1 and 114-3 are fully disposed over the respective gate structures 108 below them. In some embodiments, the dielectric gate cap 114-2 is formed to expose a portion of the respective gate structures 108 below it.

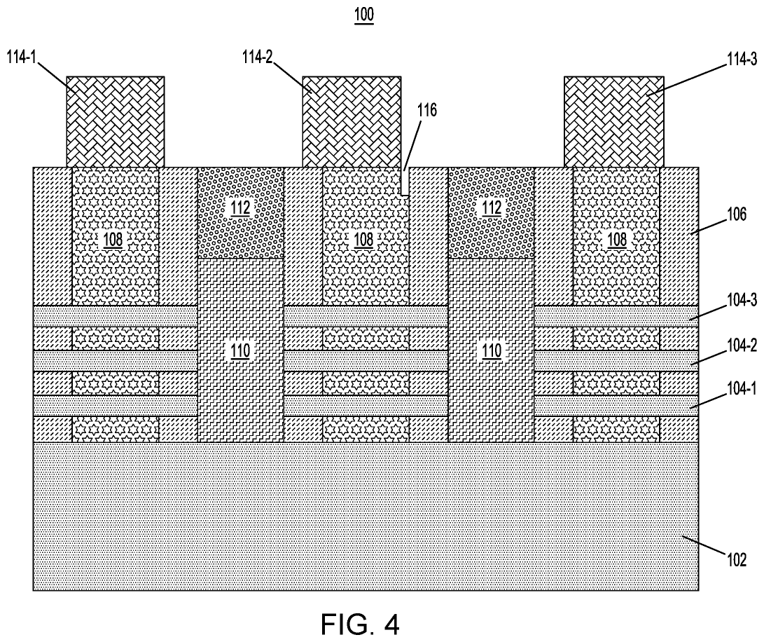

Referring now to FIG. 4, the semiconductor structure 100 is shown following formation of a gate recess region, according to an embodiment of the invention. In some embodiments, a gate recess region 116 is formed by selectively recessing the portion of the gate structures 108 exposed by the dielectric gate cap 114-2 utilizing conventional lithographic and etching processes such as a conventional wet or dry etch. The gate recess region 116 is arranged between the gate structures 108 and a given one of the gate sidewall spacers 106. The gate recess region 116 advantageously avoids a source/drain to gate short as well as any reliability issues such as dielectric breakdown.

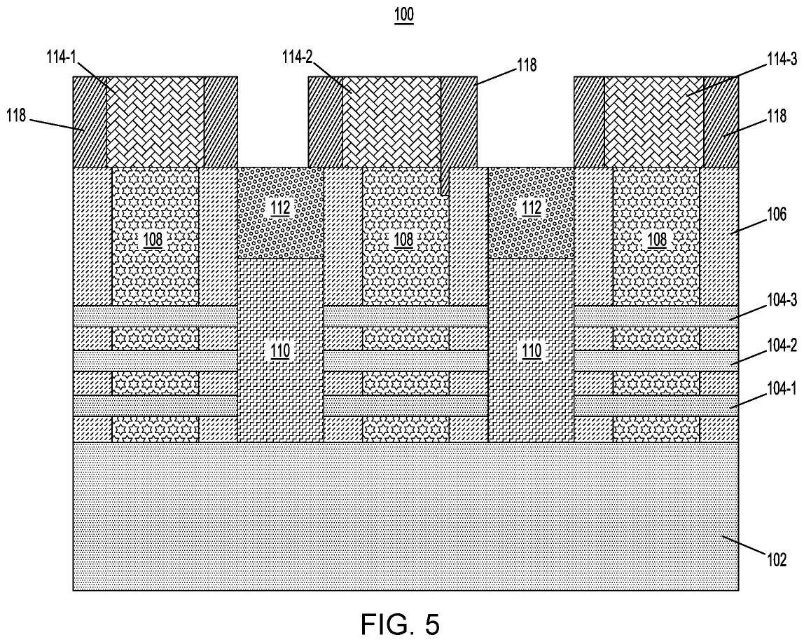

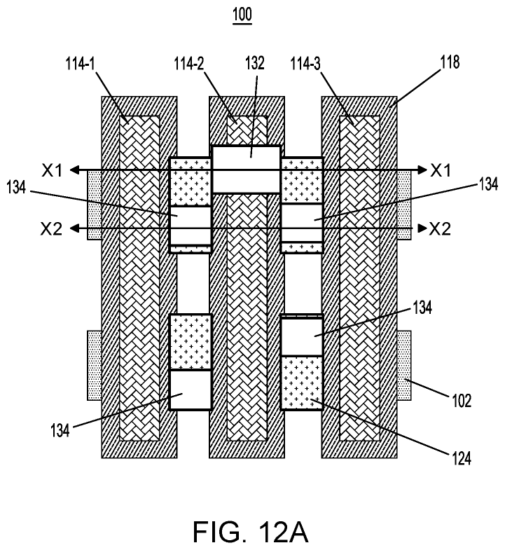

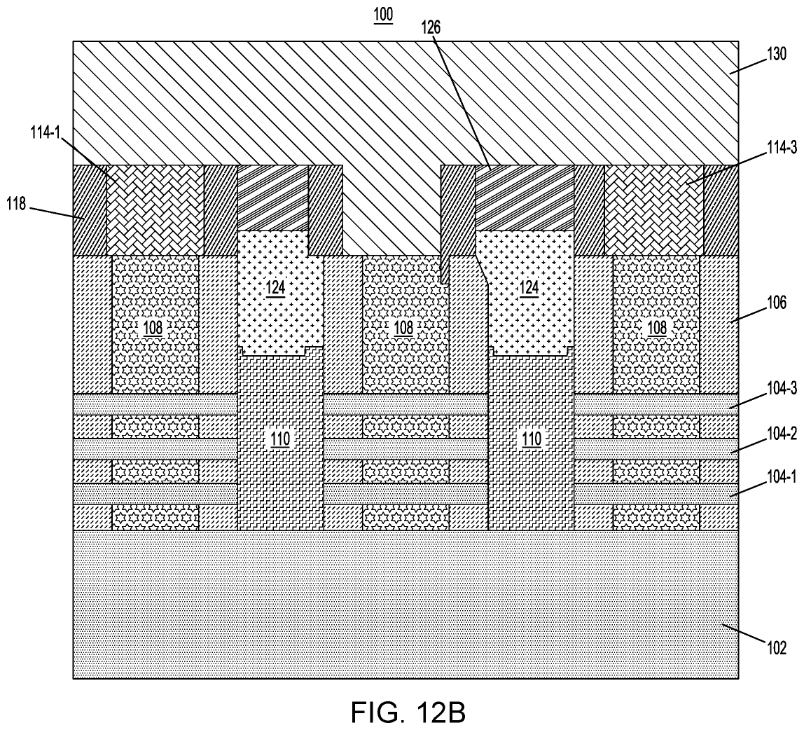

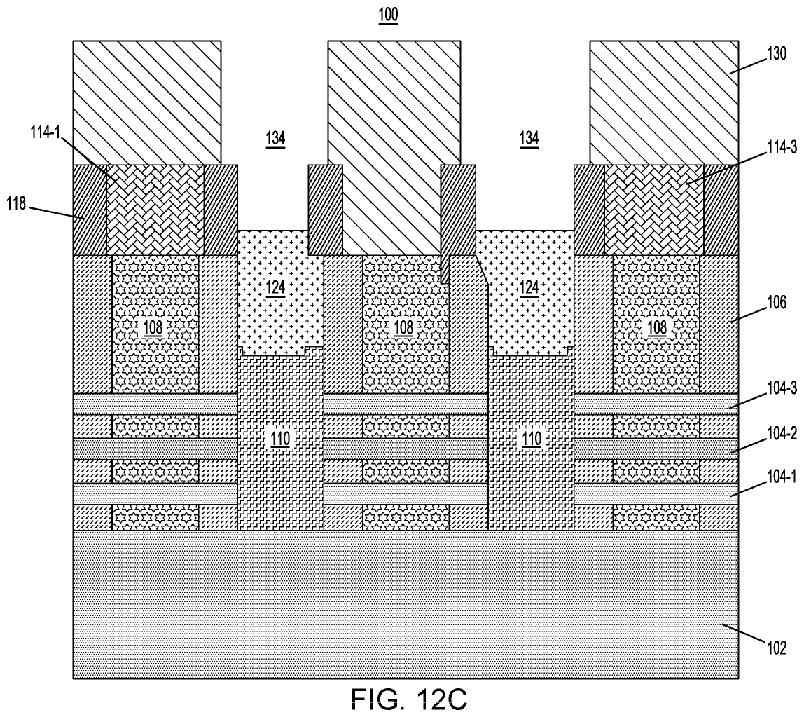

Referring now to FIG. 5, the semiconductor structure 100 is shown following deposition of a dielectric sidewall spacer, according to an embodiment of the invention. A dielectric sidewall spacer 118 is formed by depositing a dielectric material on lateral sides of the dielectric gate caps 114-1, 114-2, and 114-3 and on a top surface of the gate sidewall spacers 106 so as to extend into and fill the gate recess region 116, referred to in FIG. 4, thereby extending the dielectric sidewall spacer 118 into the gate structures 108 through the gate recess region. In some embodiments, the dielectric sidewall spacer 118 is formed of a dielectric material having a higher k-value than the dielectric material for the dielectric gate caps 114-1, 114-2, and 114-3 and the gate sidewall spacers 106. In some embodiment, the dielectric sidewall spacer 118 surrounds the dielectric gate caps 114-1, 114-2, and 114-3 (see FIG. 12A). Suitable dielectric material for forming the dielectric sidewall spacer 118 includes, for example, silicoboron carbonitride (SiBCN). Advantageously, the dielectric spacer material with a higher k-value used to form the dielectric sidewall spacer 118 provides better protection to the lower k dielectric material used to form the gate sidewall spacers 106.

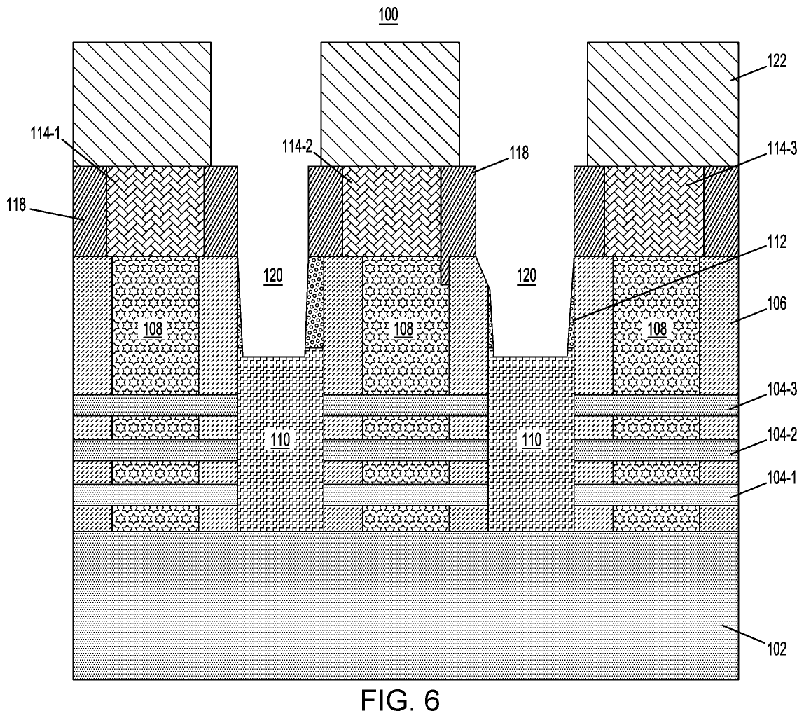

Referring now to FIG. 6, the semiconductor structure 100 is shown following patterning and etching vias in an ILD layer to form source/drain contact openings, according to an embodiment of the invention. In some embodiments, a mask layer 122 (such as an organic planarization layer (OPL) or a spin-on-carbon (SOC)) is deposited on top portions of the dielectric gate caps 114-1, 114-2, and 114-3 and the dielectric sidewall spacer 118 using, for example, a spin-on coating or any other suitable deposition process. Next, the mask layer 122 is patterned and a selective etch process such as RIE can be carried out to selectively remove the exposed portion of the mask layer 122, a portion of the ILD layer 112, and additionally to selectively etch through a portion of the source/drain regions 110 to form source/drain contact openings 120. In the selective etch process, a portion of a gate sidewall spacer of the gate sidewall spacers 106 adjacent to the gate recess region filled by the dielectric sidewall spacer 118 is also etched resulting in a tapered side surface, i.e., the sidewall of the dielectric sidewall spacer 118 opposite the sidewall disposed on the gate structures 108 has a tapered edge. In some embodiments, a sidewall of the dielectric sidewall spacer 118 is substantially aligned with the edge of the tapered side surface starting on the top surface of the respective gate sidewall spacer of the gate sidewall spacers 106.

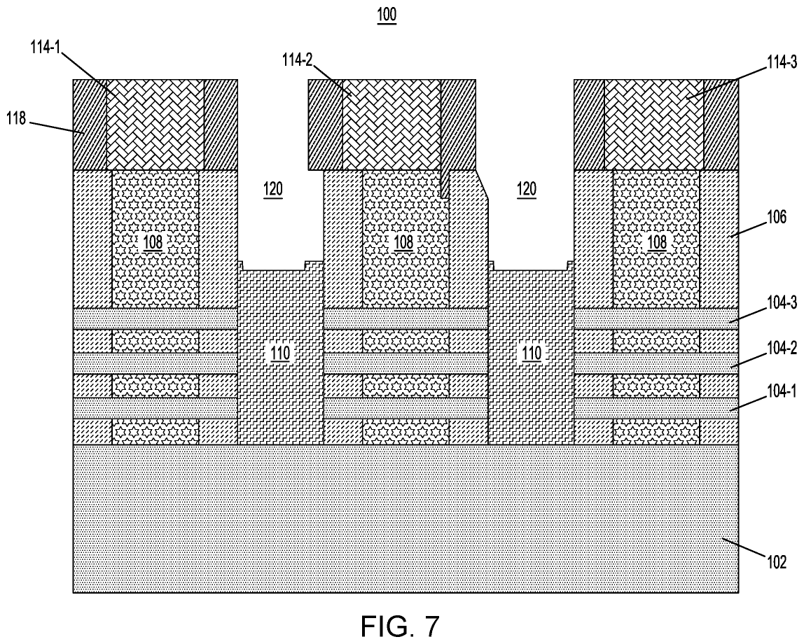

Referring now to FIG. 7, the semiconductor structure 100 is shown following enlarging and cleaning the source/drain contact openings 120, according to an embodiment of the invention. First, the mask layer 122 is removed by, for example, an ash etching process. Then, in some embodiments, a contact opening enlargement clean may be done which may enlarge a size of the source/drain contact openings 120 and remove any native oxide over the source/drain regions 110. In addition, the remaining portion of the ILD layer 112 is removed thereby increasing the size of the source/drain contact openings 120. In some embodiments, a contact opening enlargement clean may be performed using, for example, a dilute hydrofluoric acid (DHF) wet clean process and/or a SiCoNi™ dry clean process.

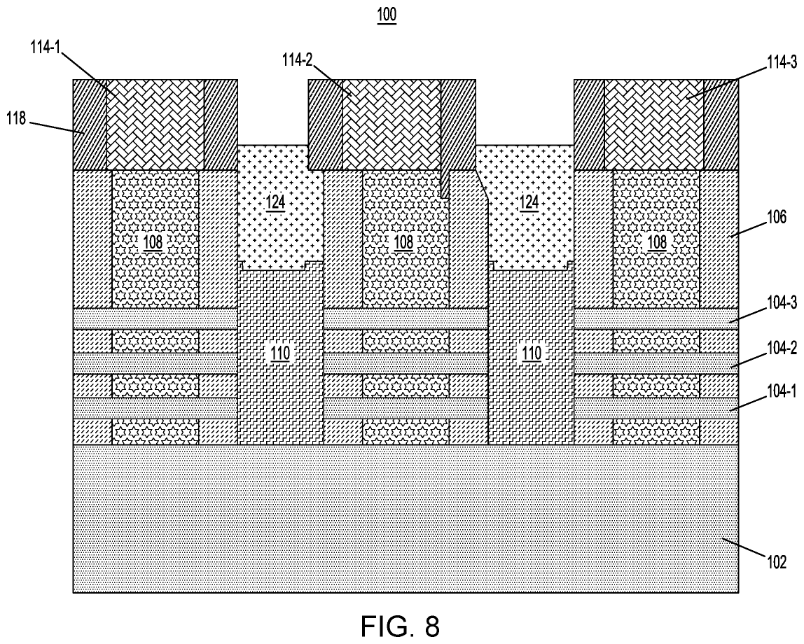

Referring now to FIG. 8, the semiconductor structure 100 is shown following formation of metal source/drain metal contacts, according to an embodiment of the invention. Source/drain metal contacts 124 are formed in the source/drain contact openings 120 using any conventional deposition technique such as ALD, CVD, PVD, electroplating, etc. Suitable metals for the source/drain metal contacts 124 include, for example, any conductive material such as a silicide liner such as Ti, Ni, NiPt, a metal adhesion layer TiN, TaN, and a conductive metal such as tungsten (W), aluminum (Al), copper (Cu), cobalt (Co), ruthenium (Ru), molybdenum (Mo), or any other suitable conductive material. The conductive metal can be recessed using, for example, a planarizing process such as CMP, followed by dry etch or wet etch.

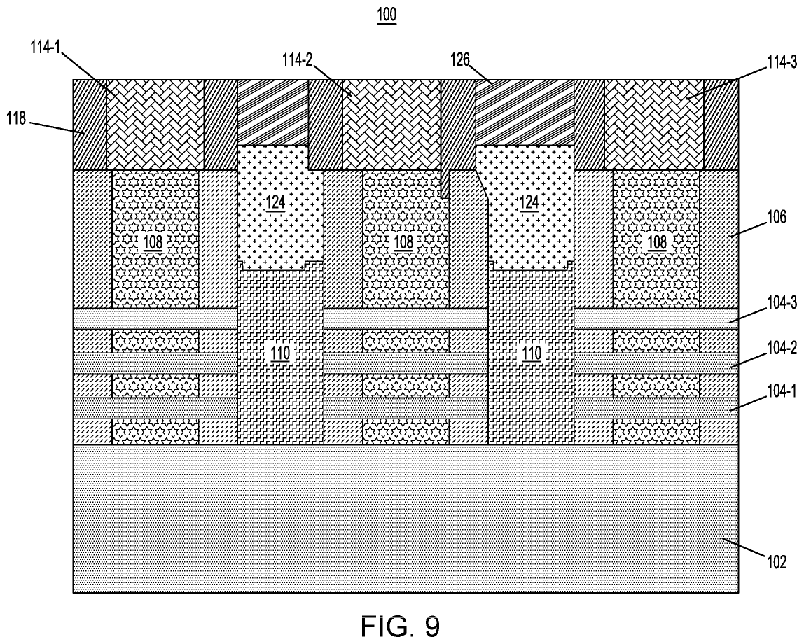

Referring now to FIG. 9, the semiconductor structure 100 is shown following deposition of an ILD layer, according to an embodiment of the invention. An ILD layer 126 is deposited over the source/drain metal contacts 124, followed by a planarization process such as CMP. The ILD layer 126 can be formed using similar processes and of similar material as the ILD layer 112.

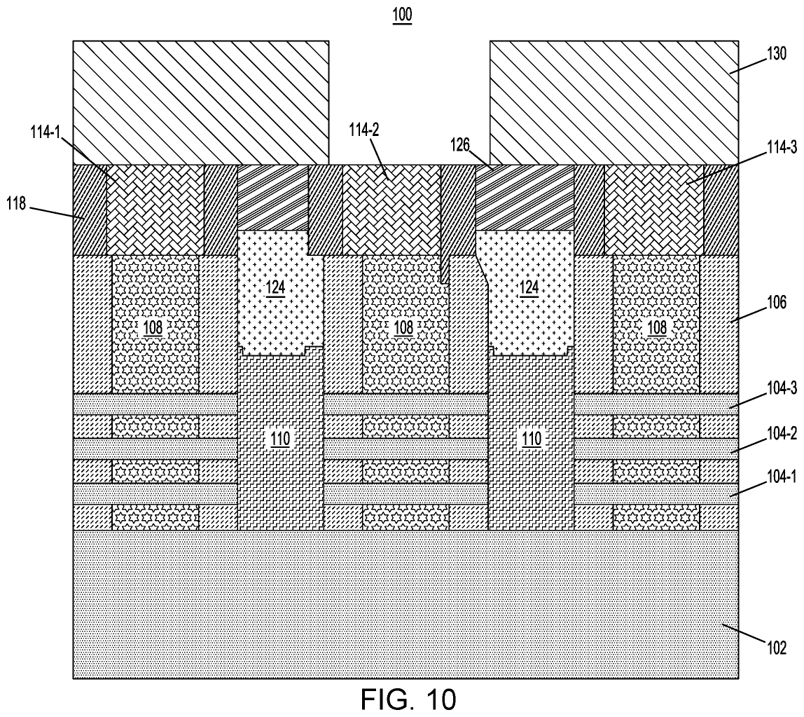

Referring now to FIG. 10, the semiconductor structure 100 is shown following deposition and patterning of a mask layer, according to an embodiment of the invention. First, a mask layer 130 is deposited on top portions of the ILD layer 126, the dielectric gate caps 114-1, 114-2, and 114-3 and the dielectric sidewall spacer 118. The mask layer 130 can be formed using similar processes and of similar material as the mask layer 122. Next, the mask layer 130 is subjected to standard lithographic and patterning techniques to form an opening exposing the dielectric gate cap 114-2 and the ILD layer 126.

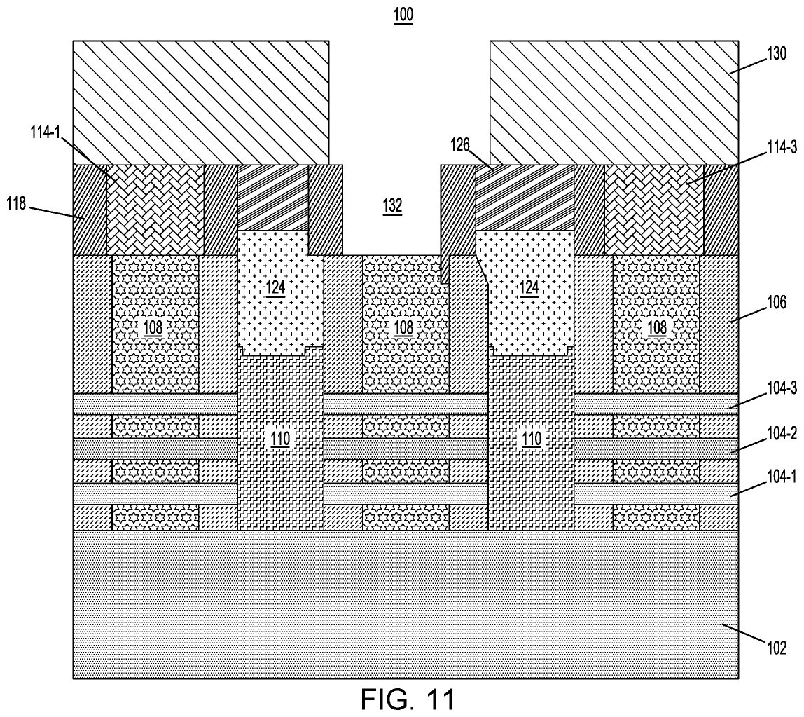

Referring now to FIG. 11, the semiconductor structure 100 is shown following formation of a gate contact opening, according to an embodiment of the invention. A gate contact opening 132 is formed by selectively etching the dielectric gate cap 114-2 using, for example, RIE.

Referring now to FIGS. 12A-12C, the semiconductor structure 100 is shown following deposition of an additional mask layer, followed by patterning and etching source/drain contact vias, according to an embodiment of the invention. The mask layer 130 is deposited on the semiconductor structure including in the gate contact opening 132, referred to in FIG. 11, followed by a planarization process such as CMP as shown in FIG. 12B. The mask layer 130 is then patterned and a selective etch process such as RIE can be carried out to selectively etch and remove the exposed portions of the mask layer 130 and the ILD layer 126 to form metal via openings 134 and exposing a top surface of the source/drain metal contacts 124.

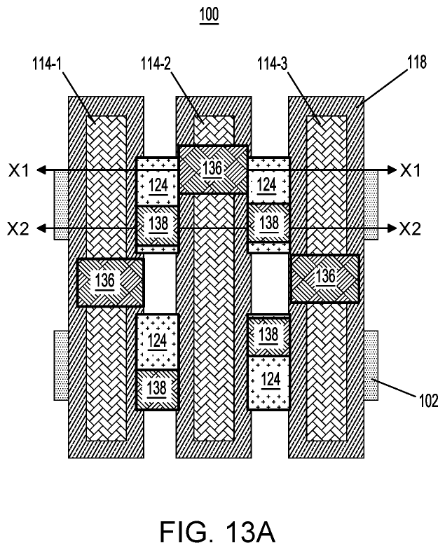

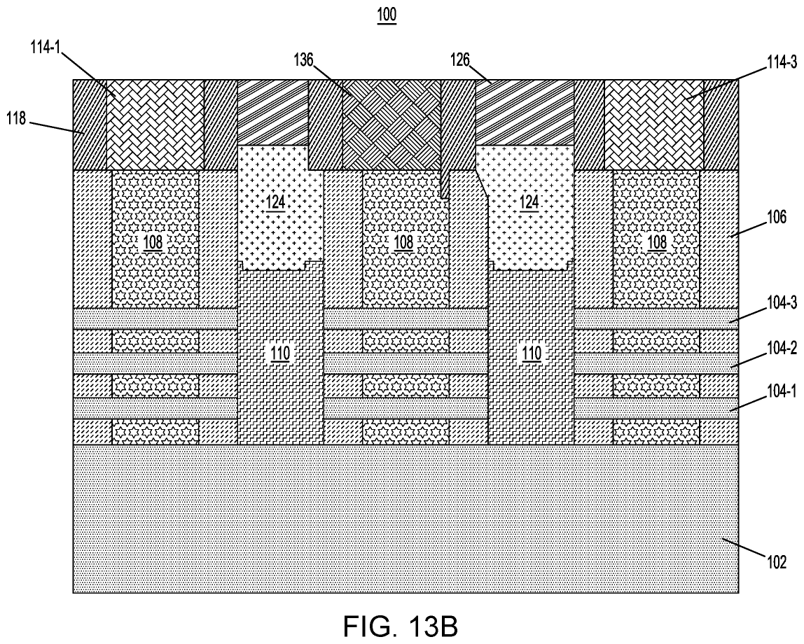

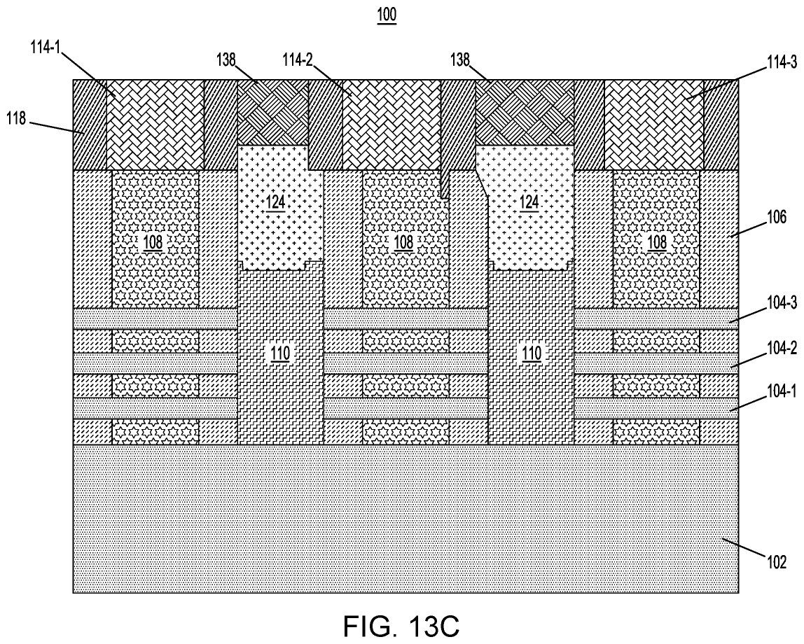

Referring now to FIGS. 13A-13C, the semiconductor structure 100 is shown following formation metal gate contacts and metal vias, according to an embodiment of the invention. A conductive metal is deposited in the metal via openings 134 to form metal vias 138. The mask layer 130 is removed using any known technique such as an ash etching process. Next, metal gate contacts 136 are formed by depositing a suitable conductive metal in the openings. The metal gate contacts 136 and the metal vias 138 can be formed by similar processes and similar conductive metals as the source/drain metal contacts 124. In some embodiments, the source/drain metal contacts 124 are lower than the metal gate contacts 136. The conductive metal can then be planarized using, for example, a planarizing process such as CMP. Other planarization processes can include grinding and polishing.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
gate sidewall spacers disposed on sidewalls of a gate structure;
a dielectric gate cap disposed over a portion of the gate structure; and
a dielectric sidewall spacer disposed on sidewalls of the dielectric gate cap and on the gate structure, wherein the dielectric sidewall spacer extends into a gate recess region arranged between the gate structure and a given one of the gate sidewall spacers and surrounds the dielectric gate cap.

2. The semiconductor structure according to claim 1, further comprising a metal gate contact disposed within the dielectric gate cap.

3. The semiconductor structure according to claim 2, wherein the dielectric sidewall spacer is disposed on lateral sides of the metal gate contact.

4. The semiconductor structure according to claim 2, further comprising a source/drain region disposed adjacent the gate structure, and a source/drain metal contact disposed on the source/drain region.

5. The semiconductor structure according to claim 4, wherein the source/drain metal contact is lower than the metal gate contact.

6. The semiconductor structure according to claim 4, further comprising a metal via disposed on the source/drain metal contact.

7. The semiconductor structure according to claim 1, wherein the dielectric sidewall spacer comprises a high-K dielectric material and the gate sidewall spacers comprise a low-k dielectric material.

8. The semiconductor structure according to claim 1, wherein the given one of the gate sidewall spacers comprises a tapered side surface.

9. A semiconductor structure, comprising:
first gate sidewall spacers disposed on sidewalls of a first gate structure on a first channel region;
a first dielectric gate cap disposed over a portion of the first gate structure;
a first dielectric sidewall spacer disposed on sidewalls of the first dielectric gate cap, wherein the first dielectric sidewall spacer extends into a gate recess region arranged between the first gate structure and a given one of the first gate sidewall spacers and surrounds the first dielectric gate cap;
second gate sidewall spacers disposed on sidewalls of a second gate structure on a second channel region adjacent the first channel region;
a second dielectric gate cap disposed over the second gate structure; and
a second dielectric sidewall spacer disposed on sidewalls of the second dielectric gate cap and surrounds the second dielectric gate cap.

10. The semiconductor structure according to claim 9, further comprising a metal gate contact disposed within the first dielectric gate cap.

11. The semiconductor structure according to claim 10, wherein the first dielectric sidewall spacer is disposed on lateral sides of the metal gate contact.

12. The semiconductor structure according to claim 10, further comprising a source/drain region disposed between the first gate structure and the second gate structure, and a source/drain metal contact disposed on the source/drain region.

13. The semiconductor structure according to claim 12, wherein the source/drain metal contact is lower than the metal gate contact.

14. The semiconductor structure according to claim 12, further comprising a metal via disposed on the source/drain metal contact.

15. The semiconductor structure according to claim 9, wherein the first dielectric sidewall spacer and the second dielectric sidewall spacer each comprise a high-K dielectric material and the first gate sidewall spacers and the second gate sidewall spacers each comprise a low-k dielectric material.

16. The semiconductor structure according to claim 9, wherein the given one of the first gate sidewall spacers comprises a tapered side surface.

17. An integrated circuit, comprising:
one or more semiconductor structures, wherein at least one of the one or more semiconductor structures comprises:
gate sidewall spacers disposed on sidewalls of a gate structure;
a dielectric gate cap disposed over a portion of the gate structure; and
a dielectric sidewall spacer disposed on sidewalls of the dielectric gate cap and on the gate structure, wherein the dielectric sidewall spacer extends into a gate recess region arranged between the gate structure and a given one of the gate sidewall spacers and surrounds the dielectric gate cap.

18. The integrated circuit according to claim 17, wherein the at least one of the one or more semiconductor structures further comprises:
a metal gate contact disposed within the dielectric gate cap, wherein the dielectric sidewall spacer is disposed on lateral sides of the metal gate contact;
a source/drain region disposed adjacent the gate structure; and
a source/drain metal contact disposed on the source/drain region, wherein the source/drain metal contact is lower than the metal gate contact.

19. The integrated circuit according to claim 17, wherein the dielectric sidewall spacer comprises a high-K dielectric material and the gate sidewall spacers comprise a low-k dielectric material.

20. The integrated circuit according to claim 17, wherein the given one of the gate sidewall spacers comprises a tapered side surface.
